(19) United States
(12) Patent Application Publication
(10) Pub. No.: US 2024/0114109 A1
(43) Pub. Date: Apr. 4, 2024

(54) CABLE NETWORK DEVICE WITH LOW LOSS MEASUREMENT PORT

(71) Applicant: TECHNETIX B.V., Veenendaal (NL)

(72) Inventors: Jan ARIESEN, Veenendaal (NL); Premton BOGAJ, Veenendaal (NL); Matthijs LARO, Veenendaal (NL)

(21) Appl. No.: 18/243,187

(22) Filed: Sep. 7, 2023

(30) Foreign Application Priority Data
Oct. 4, 2022 (GB) 2214602.1

(51) Int. Cl. H04N 7/10; H01P 5/18; H03F 1/18; H03H 7/48; H04B 3/466

(52) U.S. Cl. CPC H04N 7/102; H01P 5/187; H03F 1/18; H03H 7/482; H04B 3/466; H03F 2200/165; H03F 2200/63

(57) ABSTRACT

There is provided a cable network device (10) comprising an output path (32), for example from a diplex filter, connected to at least one output (14) and a test port (24′) associated with the at least one output (14), wherein a microstrip directional coupler (30) is disposed in the output path (32) with a coupling port (44) of the microstrip directional coupler (30) connected to the test port (24′), and an amplifier element (36) and at least one equalizer (34) disposed between the coupling port (44) and the test port (24′). The device is configured for signals complying with a high frequency spectrum of 1.8 GHz and above.

### FIELD OF THE INVENTION

This invention relates to a cable network device with a low loss measurement port.

### BACKGROUND TO THE INVENTION

In cable networks, electrically powered devices known as active devices are provided with one or more measuring ports where technicians can measure the frequency spectrum of the signal and if necessary modify those signals. Amplifiers are one type of such active devices and have a measuring port associated with an output port. As active devices are re-configured to operate effectively for different signal standards, losses associated with the test port introduce technical limitations which affect the design of the active device.

### SUMMARY OF THE INVENTION

In accordance with the present invention, there is provided a cable network device comprising an output path, for example from a diplex filter, connected to at least one output and a test port associated with the at least one output, wherein a microstrip directional coupler is disposed in the output path with a coupling port of the microstrip directional coupler connected to the test port, and an amplifier element and at least one equalizer are disposed between the coupling port and the test port. This assists with re-configuring the cable network device to be suitable for higher frequencies as the saving in insertion loss ensures less power needs to be routed to the device to overcome the insertion loss associated with the test port.

The at least one equalizer is preferably disposed between the amplifier element and the test port. Alternatively, or in addition, an equalizer may be disposed between the coupling port and the test port. Thus two equalizers may be provided, a first equalizer disposed between the amplifier element and the test port and a second equalizer disposed between the coupling port and the test port.

Preferably the output is connected to the output port of the microstrip directional coupler.

The device is preferably an active device in a CATV network, such as an amplifier device, line extender, node amplifier or booster amplifier, requiring electrical power to operate.

The cable network device is preferably configured for signals complying with a high frequency spectrum of 1.8 GHz and above.

The invention will now be described by way of example in relation to the following drawings in which:

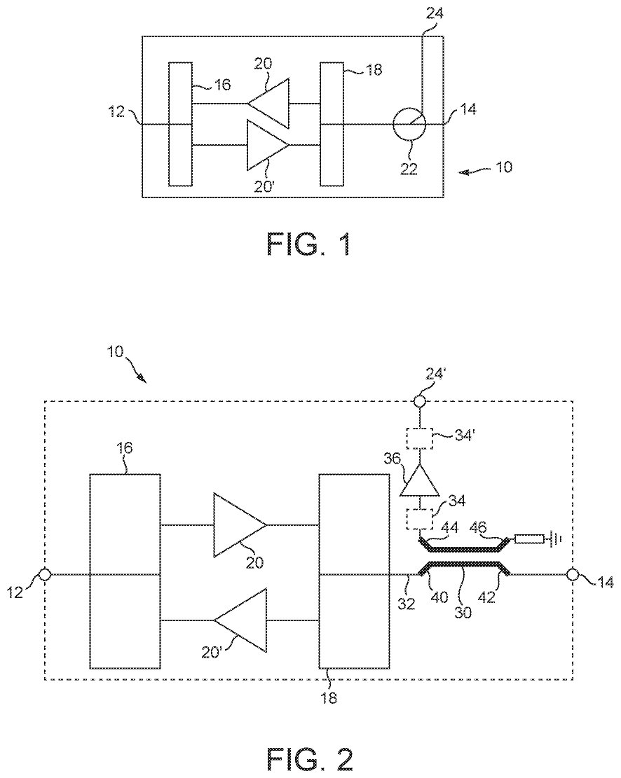

FIG. 1 is a schematic diagram of an amplifier device with a prior art test port; and

FIG. 2 shows schematic diagrams of part of an amplifier device with a modified test port based on a microstrip directional coupler;

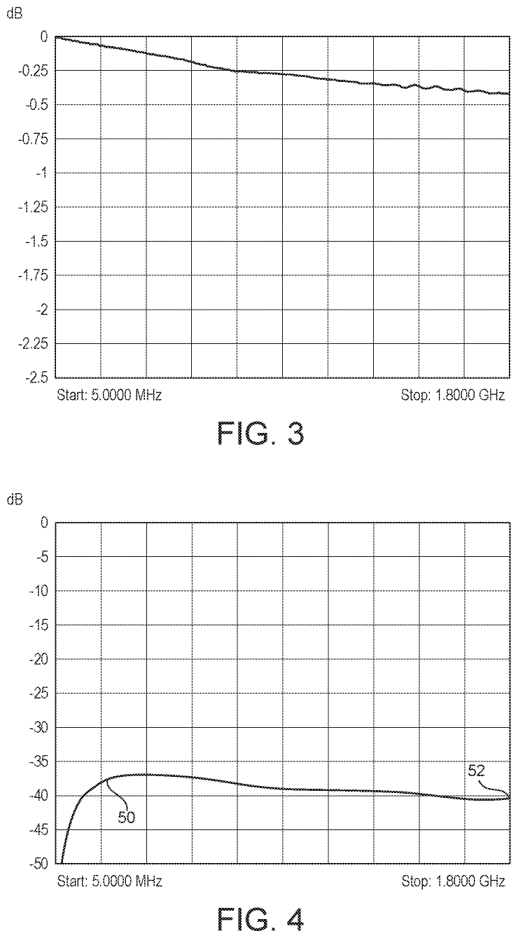

FIG. 3 is a graph showing insertion loss characteristics for the arrangement of FIG. 2; and

FIG. 4 is a graph showing signal response of the microstrip directional coupler combined with an equalizer.

### DESCRIPTION

An illustrative example of an active cable network device being an amplifier device 10 as used in a broadband and/or cable television (CATV) network is shown in FIG. 1. Amplifier device 10 comprises an input 12 and an output 14 with diplex filters 16, 18 to separate upstream and downstream signals for amplification by amplifier elements 20, 20′. Bi-directional passage of upstream and downstream signals occurs through device 10 with the configuration of electronic components and numbers of input and output ports varying depending on the network requirements. Device 10 further comprises ferrite coupler 22 disposed in a signal path to output port 14 so as to provide an output test port 24 which is connected to an RF-connector (not shown) so that the signal can be measured with an external spectrum analyser allowing a technician to measure and modify downstream and upstream signals without disconnecting amplifier device 10 from the network. Such a test port arrangement attenuates signal from the main signal line, especially for devices configured for complying with a high frequency spectrum of 1.8 GHz and above. The insertion loss (loss from input to output) can be up to 3 dB. These insertion losses result in less output power at output 14 and to offset this the power consumption of amplifier 10 has to be doubled which is difficult to achieve.

For new active devices such as amplifiers and transceivers being developed to operate with signals at higher frequencies of 1.8 GHz and above, output test port 24 is still required. To address the issues with the large insertion loss at high frequencies, a modified test port arrangement is shown in FIG. 2 where ferrite coupler 22 is replaced within amplifier device 10 by a directional microstrip coupler 30 located in output path 32 between filter 18 and output 14, together with one or more equalizer circuits 34, 34′ and an amplifier element 36. Microstrip coupler input port 40 connects to filter 18 with microstrip coupler output port 42 connected to output port 14. Coupled port 44 of coupler 30 is connected to amplifier element 36 and thence to test port 24′, with at one or two equalizers 34, 34′ disposed between test port 24′ and coupled port 44. Isolation port 46 is connected to ground.

Microstrip coupler 30 is typically selected to have a relatively long length, generally greater than 30 mm, so as to have a bandwidth similar to the downstream signal spectrum which is wide banded with frequencies in the range 200 MHz-1800 MHz. However, a shorter microstrip coupler can be used if the lower frequencies are less important to save space.

For test port 24′, it is desired to have a flat coupling response so that the signal characteristics of signals entering or leaving filter 18 are the same as the signal measured at port 24′. A tap loss of −20 dB is also preferred. Microstrip couplers have a tilted coupled response and, because the insertion loss of the coupler needs to be as low as possible, also a larger coupling loss, typically 25 dB or more. Thus a standard microstrip coupler is of no use as a measuring point over a wide bandwidth. To achieve the desired characteristics for test port 24′, one or more equalizer circuits 34, 34′ and a single amplifier element 36 are combined with microstrip directional coupler 30 to make the coupled signal of microstrip coupler 30 flat over a wide bandwidth and with dB coupling loss. The equalizer can be disposed between amplifier element 36 and coupling port 44 and/or disposed between amplifier element 36 and test port 24′.

FIG. 3 shows a typical insertion loss characteristic for an arrangement such as in FIG. 2, with insertion loss around 0.4 dB at 1800 MHz. This is a greatly reduced insertion loss compared to prior art test ports such as shown in FIG. 1.

An example of the tap loss characteristic of a microstrip directional coupler combined with equalizer is given in FIG. 4 where the tap loss value is around 40 dB at point 50 where the frequency is 200 MHz and at point 52 where the frequency is 1.8 GHz. This illustrates the flat tap loss characteristic of an arrangement as shown in FIG. 2 before amplifier element 36 is added into the path between coupler port 44 and output port 24′ so as to increase gain and so achieve the desired tap loss of −20 dB.

Measurement or test port 24′ exhibits a low insertion loss around 0.4 dB instead of 2 dB or 3 dB as with prior art measurement ports based on ferrite directional couplers. This greatly assists with re-configuring the active device to be suitable for higher frequencies within the CATV network as the saving in insertion loss ensures less power needs to be routed to the amplifier device to overcome the insertion loss associated with test port 24′.

1. A cable network device comprising an output path connected to at least one output and a test port associated with the at least one output, wherein a microstrip directional coupler is disposed in the output path with a coupling port of the microstrip directional coupler connected to the test port, and an amplifier element and at least one equalizer are disposed between the coupling port and the test port.

2. A cable network device according to claim 1, wherein the at least one equalizer is disposed between the amplifier element and the test port.

3. A cable network device according to claim 1, wherein the at least one equalizer is disposed between the coupling port and the test port.

4. A cable network device according to claim 1, wherein two equalizers are provided, a first equalizer disposed between the amplifier element and the test port and a second equalizer disposed between the coupling port and the test port.

5. A cable network device according to claim 1, wherein the output is connected to the output port of the microstrip directional coupler.

6. A cable network device according to claim 1, wherein the device is an active device requiring electrical power to operate.

7. A cable network device according to claim 1 when configured for signals complying with a high frequency spectrum of 1.8 GHz and above.
